(19) United States
(12) Patent Application Publication
(10) Pub. No.: US 2017/0059615 A1
(43) Pub. Date: Mar. 2, 2017

(54) PROBE HEAD

(71) Applicant: MPI Corporation, Hsinchu County (TW)

(72) Inventors: Hsiang-Sheng HSIEH, Hsinchu County (TW); Sang-Yi LIN, Hsinchu County (TW); Chih-Hao HSU, Hsinchu County (TW)

(21) Appl. No.: 15/191,548

(22) Filed: Jun. 24, 2016

(30) Foreign Application Priority Data
Aug. 24, 2015 (TW) 104127534

(51) Int. Cl. G01R 1/073

(52) U.S. Cl. CPC G01R 1/07364; G01R 1/07314

(57) ABSTRACT

A probe head includes a first guiding board, a second guiding board, a spacer, a positioning assembly and probes. The second guiding board is stacked over the first guiding board, in which an accommodating space is formed between the first guiding board and the second guiding board. The spacer is disposed on the second guiding board and is located in the accommodating space. The positioning assembly is disposed aid supported on the second guiding board and is movably retained between the spacer and the first guiding board, and the positioning assembly includes a supporting frame and a film. The supporting frame includes at least one rib portion. The film is fixed to the supporting frame. The probes pass through the first guiding board, the second guiding board, and the film.

### RELATED APPLICATIONS

This application claims priority to Taiwanese Application Serial Number 104127534, filed Aug. 24, 2015, which is herein incorporated by reference.

### BACKGROUND

Field of Invention

The present invention relates to a probe head. More particularly, the present invention relates to a probe head of vertical probe card.

Description of Related Art

Reference is made to FIG. 6 which is a schematic view of a conventional vertical probe card 4. The conventional vertical probe 4 card includes a circuit board 40, a space converter board 41, and a probe head 42. The space converter board 41 is disposed on a bottom surface of the circuit board 40. The probe head 42 is disposed in the space converter hoard 41. The probe head 42 has an upper guiding board 421, a lower guiding board 422, a positioning plate 423 which is disposed between the upper guiding board 421 and the lower guiding board 422, and plural probes 420 pass through the upper guiding board 421, the lower guiding board 422, and the positioning plate 423. While being assembled, the positioning plate 423 is supported at a predetermined height away from the lower guiding board 422, and then the probes 420 are inserted through the positioning plate 423 and the lower guiding board 422. Thereafter, the upper guiding board 421 is used to cover the positioning plate 423 so as to keep the probes 420 upright, and then the probes 420 protruding from the upper guiding board 421 are electrically connected to contacts at a lower surface of the space converter board 41. In addition, contracts at an upper surface of the space converter board 41 are electrically connected to the circuit board 40, and a pitch of two adjacent contacts at the upper surface of the space converter board 41 is greater than that at the lower surface of the space converter board 41. Hence, the vertical probe 4 may point contact contacts at wafer dies (devices under test; DUTs) through tip portions of the probes 420 protruding the lower guiding board 422, so as to perform a test project. If the positioning plate 423 is not fixed in the probe card 42, the positioning plate 423 may shift along with the probes 420 when the probes 420 contact the DUT. On the contrary, if the positioning plate 423 is fixed in the test device 42, positions of the probes 420 is restricted by the positioning plate 423, and thus the probes 420 are at poor positions, thus leading to poor electrical contacts between the probes 420 and the contacts of the DUT or the space converter board 41, or causing the probes 420 to be damaged.

Moreover, in practical applications, the probes may need maintenance such as probe replacement after a long period of operation. When the probes 420 of the probe head 42 of the conventional vertical probe 4 is in maintenance, the upper guiding board 421 has to be first removed, and then the probes 420 are extracted out. However, because the position plate 423 is formed from a flexible material, the position plate 423 will be deformed if not being fixed by proper support, and the deformation will be more apparent when the position plate 423 has a larger surface area. Moreover, in the replacement of one of the probes 420, if the probe 420 plucks the positioning plate 423 and pops up, other probes will escape from the positioning plate 423 and become unfixed, and thus subsequent assembly operations have to be started over again, thus increasing the difficulty of maintenance and labor and time costs, even damaging the popped out probe 420 and increasing expenditure.

### SUMMARY

One of the embodiments in the disclosure provides a probe head includes a first guiding board, a second guiding board, a spacer, a positioning assembly and probes. The second guiding board is stacked over the first guiding board, in which an accommodating space is formed between the first guiding board and the second guiding board. The spacer is disposed on the second guiding board and is located in the accommodating space. The positioning assembly is disposed and supported on the second guiding board, and is movably retained between the spacer and the first guiding board, and the positioning assembly includes a supporting frame and a film. The supporting frame comprises at least one rib portion. The film is fixed to the supporting frame. The probes pass through the first guiding board, the second guiding board, and the film, in which the probes at least forma first probing zone and a second probing zone. A non-probing zone is formed between the first probing zone and the second probing zone. The rib portion is located in the non-probing zone. A width of the rib portion is larger than twice of a distance between two adjacent ones of the probes in the first probing zone.

According to the structural arrangement of the present disclosure, the probe head of the present disclosure includes a movable positioning assembly which is disposed between the first guiding board and the second guiding board, in which the film of the positioning assembly may be used for positioning the probes passing through the film. The supporting frame of the positioning assembly may be used for supporting and restricting the film so as to prevent the film from drooping in the normal use or to prevent other probes from being separated from the film in the replacement of one of the probes (in which the probe may pluck the film to cause the separation and then losing supports). Specifically, the supporting frame supports and restricts the film by the rib portion extending between two adjacent ones of the probing zones. By using the rib portion extending between two adjacent ones of the probing zones, the excessive deformation of the film around the probing zones (especially between the probing zones) can be avoided, and the aforementioned drooping and plucking problems can be prevented.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of a probe head in accordance with some embodiments of the present disclosure.

FIG. 2 is a schematic cross-sectional view of a probe head of FIG. 1 viewed along a line 2-2′.

FIG. 3 is a schematic cross-sectional view of a probe head in accordance with some embodiments of the present disclosure.

FIG. 4 is a schematic cross-sectional view of a probe head in accordance with some embodiments of the present disclosure.

FIG. 5 is a schematic cross-sectional view of a probe head in accordance with some embodiments of the present disclosure.

FIG. 6 is a schematic view of a conventional vertical probe card.

### DETAILED DESCRIPTION

The following disclosures feature of several embodiments so that those skilled in the art may better understand the aspects of the present disclosure. Those skilled is the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

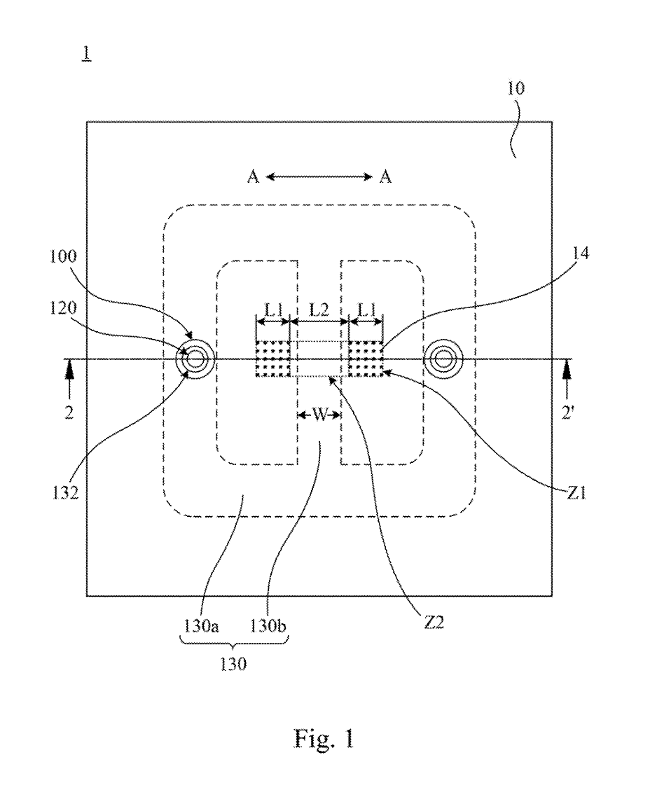

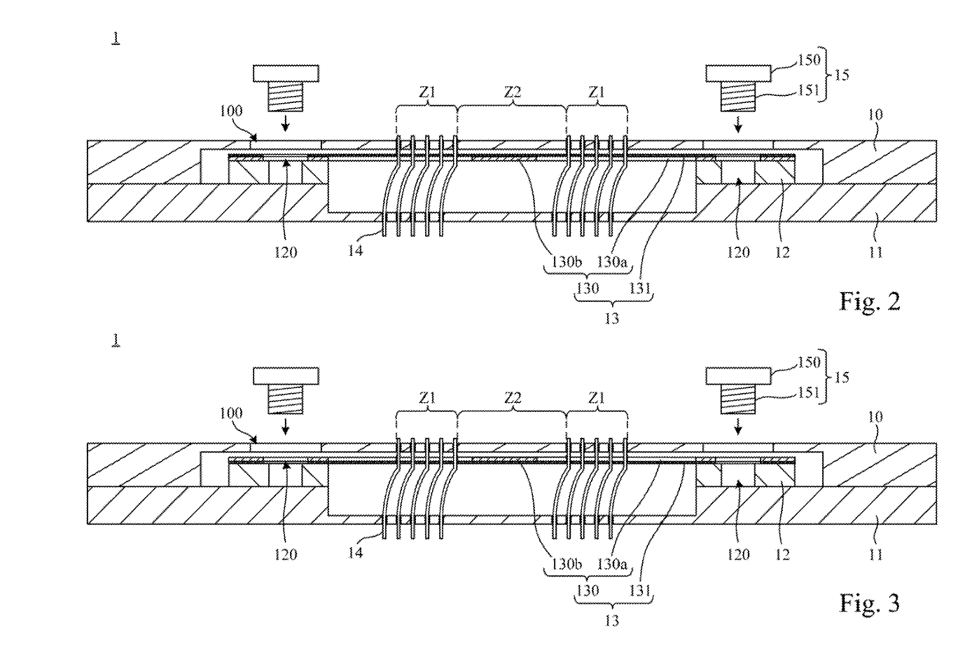

Reference is made to FIG. 1 and FIG. 2. FIG. 1 is a schematic top view of a probe head in accordance with some embodiments of the present disclosure. FIG. 2 is a schematic cross-sectional view of a probe head of FIG. 1 viewed along a line 2-2′. As shown in FIG. 1, in the embodiments, a probe head 1 includes a first guiding board 10, a second guiding board 11, a spacer 12, a positioning assembly 13 and plural probes 14. The structure and function, of the elements and the relationship therebetween are described in detail hereinafter.

The second guiding board 11 is stacked over the first guiding board 10. An accommodating space is formed between the first guiding board 10 and the second guiding board 11. The spacer 12 is disposed on the second guiding board 11, and is located in the accommodating space. In some embodiments, the first guiding board 10 and the second guiding board 11 may be fixed to each other by screws, but the present invention is not limited thereto.

The positioning assembly 13 is disposed and supported on the spacer 12, and is movably retained between the spacer 12 and the first guiding board 10. In other words, the distance between the spacer 12 and the first guiding board 10 is greater than the thickness of the positioning assembly 13. The positioning assembly 13 includes a supporting frame 130 and a film 131. The supporting frame 130 includes at least one rib portion 130b. The film 131 is adhered to or disposed on the supporting frame 130, and the film 131 is made of an insulating material which is not electrically conductive.

The probes 14 are inserted through holes on the first guiding board 10, the second guiding board 11, and the film 131, and form plural probing zones Z1. The probes 14 are made of a metal material with good electrical conductivity. On a practical application, each of the probes zones Z1 may point contact at least one DUT on a wafer, and the DUTs are referred to as dies. The quantity of the probes 14 which pass through the probes zones Z1 shown in FIG. 1 is twenty five in five rows and five columns, but the present disclosure is not limited thereto.

In some embodiments, the film 131 faces the first guiding plat e10, and the supporting frame 130 faces the spacer 12. In some embodiments, the film is adhered to the supporting frame 130. Specifically speaking, the supporting frame 130 further includes a frame body 130a, and the rib portion 130b is connected to an inner edge of the frame body 130a, and the film 131 is adhered to the frame body 130a and the rib portion 130b of the supporting frame 130. Specifically speaking, a non-probing zone Z2 is formed between two adjacent ones of the probing zones Z1. The rib portion 130b is located in the non-probing zone Z2, and the probes 14 do not pass through the non-probing zone Z2 and the rib portion 130b, thereby enabling the supporting frame 130 to support and restrict the film 131, thus avoiding excessive deformation of the film 131 around the probing zones Z1 (especially the area corresponding to the non-probing zone Z2), and preventing other probes from being separated from the film due to the replacement of one of the probes plucking the film. Specifically, the supporting frame 130 supporting and restricting the film 131 may prevent the film from drooping in the normal use or prevent other probes from being separated from the film due to the replacement of one of the probes plucking the film and then losing supports.

In some embodiments, a length of a side of the film 131 is greater than 10 mm. For the film 131 of which a length of the side is greater than 10 mm, the deformation of the probe head 1 generally tends to be large in normal use or the replacement of the probes 14 because the film 131 has a larger area. The supporting frame 130 provided for supporting and restricting the film 131 may prevent the excessive deformation problem of the film 131.

In some embodiments, the first guiding board 10 has a through hole 100. The probe head 1 further includes a fixing member. The fixing member is configured to detachably fix the positioning assembly 14 to the spacer 12 through the through hole 100 of the first guiding board 10. Specifically, in some embodiments, the spacer 12 has a screw hole 120, and the positioning portion is a screw 15 which fixes the spacer 12 to the screw hole 120, thereby enabling the positioning assembly 13 to be fixed to the spacer 12. When the probe head 1 is assembled, the positioning assembly 13 is first fixed to the second guiding board 11 through the locking structure disposed between the screw 15 and the screw hole 120. Then, the probes 14 are aligned with a passing hole on the first guiding board 10 to cover the first guiding board 10. Then, the screw 15 is removed to finish the assembly of the probe head, thereby enabling the positioning assembly to have the floating freedom in the horizontal and vertical directions. Hence, the film 131 may shift along with the probes 14 when the probes 14 of the probe head 1 contact all of the DUTs. Therefore, positions of the probes 14 are not restricted by the film 131, and can be kept at desirable positions, thus avoiding poor electrical contacts between the probes 14 and the DUTs or the space converter board (not shown), or avoiding the problems of broken probes 14.

On the contrary, when the a portion of probes 14 needs replacement, the screw 15 is first inserted through the through hole 100 of the first guiding board 10 and the passing hole 132 of the positioning portion 13, and is locked with the screw hole 120 of the spacer 12, thereby fixing the positioning assembly to the second guiding board 11. Then, removing the first guiding board 10, extracting the replaceable probes 14, and penetrating the good probes 14 are performed, thereby completing the replacement of the probes 14.

Further, the crew 15 has a head portion 150 and a thread portion 151. The thread portion 151 is fixed to the screw hole 120 of the spacer 12 after passing through a passing hole 332 of the positioning assembly 13.

However, the present invention is not limited thereto. On the practical application, the positioning assembly 13 may not have passing hole 132, and the thread portion 151 is screwed to the screw 120 of the spacer 52, and the head portion 150 presses an edge of the positioning assembly 13 to resist the spacer, thereby enabling the positioning assembly 13 to be fixed to the spacer 12.

In some embodiments, the second guiding board 11 and the spacer 12 may be monolithically formed.

In some embodiments, the number of the probes zones Z1 formed by the probes 14 is not limited to that shown in FIG. 1, and may be changed according to actual requirements.

In some embodiments, as shown in FIG. 1, the probing zones Z1 of the probes 14 herein are arranged by skipping one or more DUTs. That is, when each probing zone Z1 point contacts and tests a DUT, one or more DUTs between two adjacent ones of the probing zones Z1 may be skipped for point testing. Hence, the rib portion 130b of the supporting frame 130 may be disposed in an area corresponding to the DUT that is skipped and is not point tested, i.e. the non-probing zone Z2, thereby effectively using the non-probing zone.

Specifically, referring to FIG. 1, in some embodiments, two adjacent ones of the probing zones Z1 are substantially arranged along a direction A. Each of the two adjacent probing zones has a first length L1 in the direction A. The non-probing zone Z2 formed between two adjacent ones of the probing zones Z1 has a second length L2 in the direction A, and the second length L2 is larger than the first length L1. For example, for the non-probing zone Z2 corresponding to one DUT is skipped for testing, each probing zone Z1 only covers a DUT, and the non-probing zone Z2 has to cover a DUT and scribing lines between the DUT and its adjacent DUTs, thereby enabling the second length L2 to be larger than the first length L1. For the non-probing zone Z2 corresponding to plural DUTs are skipped for testing, the non-probing zone Z2 covers plural DUTs and plural scribing lines thereby enabling the second length L2 to be greater than the first length L1. That is, the non-probing zone Z2 with the aforementioned length limitation may be corresponding to one or more DUTs are skipped for testing and the corresponding scribing line or lines.

Furthermore, the rib portion 130b located in the non-probing zone Z2 has a width W in the direction A, and the width W is smaller than the second length L2 of the non-probing zone Z2, such that a portion of films 131 corresponding to the non-probing zone Z2 may be supported by the rib portion 130b of the supporting frame 130 when the probe head 1 moves along the direction A to test the DUT. In FIG. 1, a width W of the rib portion 130b is larger than four times of a distance between two adjacent ones of the probes 14 in the probing zone Z1, but the present disclosure is not limited thereto.

Reference is made to FIG. 3. FIG. 3 is a schematic cross-sectional view of a probe head in accordance with some embodiments of the present disclosure. In FIG. 3, in the embodiments, the probe head 1 includes a first guiding board 10, a second guiding board 11, a spacer 12, a positioning assembly 13, plural probes 14 and a fixing member. The structure and function of the elements and the relationship therebetween are substantially the same as those of the embodiments in FIG. 2, and the related detailed descriptions may refer to the foregoing paragraphs, and are not discussed again herein. The difference between the present embodiment and that in FIG. 2 is in that the positioning assembly 13 of the present embodiments arranged reversely to that in FIG. 2.

Specifically, in some embodiments, the supporting frame 13 of the positioning assembly 13 faces the first guiding board 10, and the film 131 of the positioning assembly 13 feces the spacer 12. In addition, the film 131 is only adhered to the frame body 130a of the supporting frame 130. Under this configuration, even though the film 131 is not adhered to the rib portion 130b of the supporting frame 130, the film 131 may still be restricted by the supporting frame 130 located above when a certain probe 14 is pulled out and replaced, thereby preventing the film 131 from being plucked, thus also avoiding the aforementioned problem of film flipping. Hence, the probe head 1 of the present embodiment may adopt a smaller area of the film 131, because the drooping deformation of the film 131 with a smaller area is not obvious in normal use and does not affect the function for positioning the probes 14 even though the film 131 is not adhered to the rib portion 130b of the supporting frame 130.

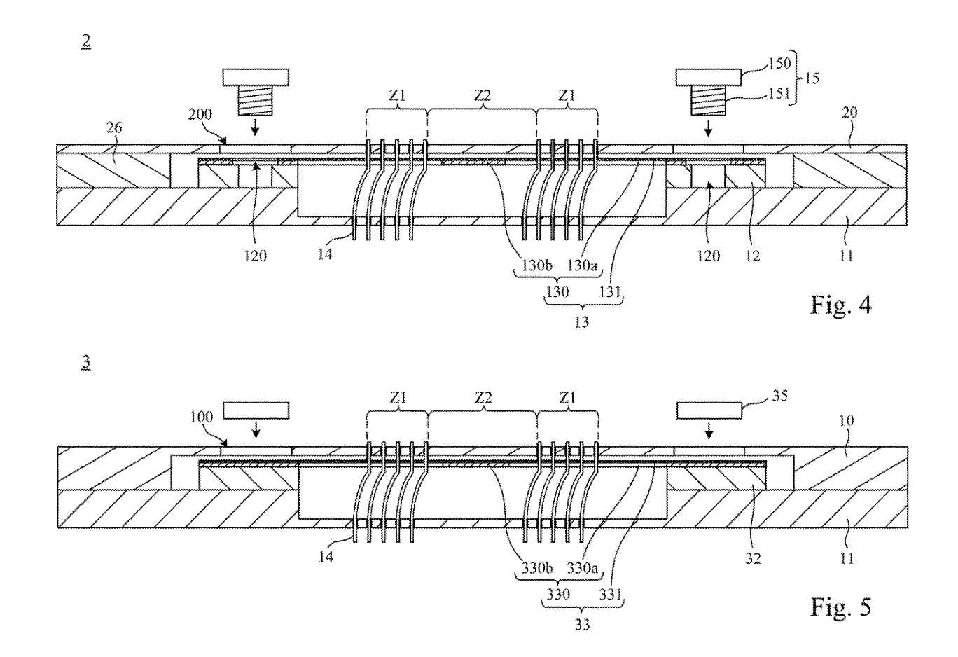

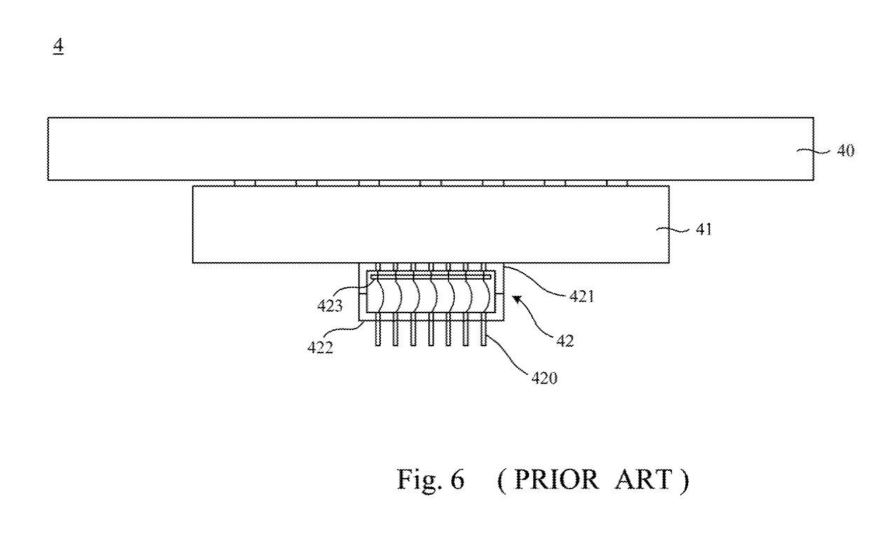

Reference is made to FIG. 4. FIG. 4 is a schematic cross-sectional view of a probe head in accordance with some embodiments of the present disclosure. In FIG. 4, in some embodiments, a probe head 2 includes a first guiding board 20, a second guiding board 11, a spacer 12, a positioning assembly 13, plural probes 14 and a fixing member. The structure and function of the elements and the relationship therebetween are substantially the same as those of the embodiments in FIG. 2, and the related detailed descriptions may refer to the foregoing paragraphs and are not discussed again herein. The difference between the present embodiment and that in FIG. 2 is in that the appearance the first guiding board 20 of the present embodiment is changed and is added with an intermediate plate 26. The first guiding board 20 has the through hole 200, and the fixing member is configured to detachably fixing the positioning assembly 13 to the spacer 12 through the through hole 200 of the first guiding board 20.

Specifically, in some embodiments, the first guiding board 20 and the second guiding board 11 are fixed to opposite sides of the intermediate plate 26. The first guiding board 20, the second guiding board 11 and the intermediate plate 26 form the aforementioned accommodating space, such that, when the height of the accommodating space (that is, the distance between the central portion of the first guiding board 20 and the second guiding board 11) needs adjusting for the practical application (using different specification of the probes 14), only the intermediate plate 26 of different specification needs replacing, without needing to replace the first guiding board 20 and the second guiding board 11. Because the structure of the intermediate plate 26 is more easily to be manufactured than the first guiding board 20 and the second guiding board 11, the cost for manufacturing the intermediate plate 26 of different specification is relatively lower for the practical application.

In some embodiments, the intermediate plate 26 may be a hollow frame surrounding the spacer 12, the positioning assembly 13, and the probes 14. In some embodiments, the intermediate plate 26 may be a dividing block disposed on two opposite sides of the spacer 12, the positioning assembly 13, and the probes 14. However, the intermediate plate 26 of the present invention is not limited thereto.

In some embodiments, the first guiding board 20 and the second guiding board 11 may be fixed to opposite sides of the intermediate plate 26 by screwing, but present invention is not limited thereto.

Reference is made to FIG. 5. FIG. 5 is a schematic cross-sectional view of a probe head in accordance with some embodiments of the present disclosure. In FIG. 5, in some embodiments, a probe head 3 includes a first guiding board 10, a second guiding board 11, a spacer 32, a positioning assembly 33, plural probes 14, and a fixing member. The structure and function of the elements and the relationship therebetween are substantially the same as those in the embodiment shown in FIG. 2, and the related detailed descriptions may refer to the foregoing paragraphs and are not discussed again herein. The difference between the present embodiments and that in FIG. 2 is in that the appearance of the spacer 32 and the positioning assembly 33 of the embodiment herein is changed. Furthermore, the fixing member is a magnetic member 35, and the spacer 32 includes a magnetic material, in which the positioning assembly 33 includes a supporting frame 330, and a film 331, and the supporting frame 330 includes a frame body 330a and a rib portion 330b.

Specifically, in some embodiments, the spacer 32 does not have the screw hole 120 of the spacer 12 shown in FIG. 2, and the positioning assembly 33 does not have the passing hole 132 of the positioning assembly 13 shown in FIG. 2. Under this configuration, when the magnetic member 35 is disposed in the through hole 100 of the first guiding board 10 and is attracted by a magnetic force of the spacer 32, the magnetic member 35 presses the positioning assembly 33 to resist the spacer 32, thereby enabling the positioning assembly 33 to be fixed to the spacer 32.

In some embodiments, a device with magnetic sensing (not shown) may be disposed under the probe head 3, thereby enabling the magnetic member 35 to be affected by a magnetic force of attraction of the device, and enabling the magnetic to have the function for fixing the positioning assembly 33 to the second guiding board 11 during the assembling of the probes 14. Certainly, the magnetic sensing descripted herein is not limited to the type of the device, and is not limited to the location of the device (i.e. the location of the device may change the direction of the magnetic field), as long as the device can attract the magnetic member 35 by a magnetic force, thus the direction of the magnetic field can induce that the magnetic member 35 presses the positioning assembly 33 to resist the second guiding board 11. On the contrary, when a portion of probes 14 need replacement, the magnetic member 35 is inserted through the through hole 100 of the first guiding board 10, and presses the positioning assembly 33 to resist the second guiding board 11 by the magnetic force of attraction, thereby enabling the positioning assembly 33 to be fixed to the second guiding board 11.

In some embodiments, the supporting frame 130 and the supporting frame 330 have first stiffness, and the film 131 and the film 331 have second stiffness, in which the first stiffness is greater than the second stiffness, thereby enabling the supporting frame 130 and supporting frame 330 to provide sufficient support to the film 131 and the film 331.

In some embodiments, each of the supporting frame 130 and the supporting frame 330 is made of a material selecting from metal, ceramics, engineering plastics or combinations thereof, but the present invention is not limited thereto.

According to the foregoing recitations of the embodiments of the disclosure, it can be seen that the probe head of the present disclosure includes a floatable positioning assembly which is disposed between the first guiding board and the second guiding board, in which the film of the positioning assembly is used for positioning the probes passing through the film. The supporting frame of the positioning assembly is sued for supporting and restricting the film to prevent the film from drooping in file normal use or to prevent other probes from being separated from the film when one of the probes is replaced and plucks the film and then lose supports. Specifically, the supporting frame supports and restricts the film by the rib portion extending between two adjacent ones of the probing zones, thus preventing excessive deformation of the film around the probing zones (especially the area between the probing zone), and avoiding the drooping and plucking problems of the film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A probe head, comprising:
a first guiding board;
a second guiding board stacked over the first guiding board, wherein an accommodating space is formed between the first guiding board and the second guiding board;
a spacer that is disposed on the second guiding board and is located in the accommodating space;
a positioning assembly that is disposed and supported on the second guiding board and is movably retained between the spacer and the first guiding board, the positioning assembly comprising:
a supporting frame comprising at least one rib portion; and
a film fixed to the supporting frame; and
a plurality of probes passing through the first guiding board, the second guiding board, and the film, wherein the probes at least form a first probing zone and a second probing zone, a non-probing zone is formed between the first probing zone and the second probing zone, the rib portion is located in the non-probing zone, and a width of the rib portion is larger than twice of a distance between two adjacent ones of the probes in the first probing zone.

2. The probe head of claim 1, wherein the film is adhered to the supporting frame.

3. The probe head of claim 1, wherein the film faces the first guiding board, and the supporting frame faces the spacer.

4. The probe head of claim 1, wherein the supporting frame faces the first guiding board, and the film faces the spacer.

5. The probe head of claim 4, wherein the supporting frame further comprises a frame body, and the rib portion is connected to an inner edge of the frame body, and the film is adhered to the frame body.

6. The probe head of claim 1, further comprising:
an intermediate board, wherein the first guiding board and the second guiding board are fixed to two opposite sides of the intermediate board respectively.

7. The probe head of claim 1, wherein the first guiding board has a through hole, and the probe head further comprises a fixing member configured to detachably fixing the positioning assembly to the spacer through the through hole.

8. The probe head of claim 7, wherein the positioning assembly has a passing hole; the spacer has a screw hole; the fixing member is a screw; the screw has a head portion and a thread portion; the thread portion passes through the passing hole and is fixed to the screw hole; and the head portion presses the positioning assembly to resist the spacer.

9. The probe head of claim 7, wherein the fixing member is a magnetic member; the spacer comprises a magnetic material; and when the magnetic member is attracted by a magnetic force of the spacer, the magnetic member presses the positioning assembly to resist the spacer.

10. The probe head of claim 1, wherein, the supporting frame is made of a material selecting from metal ceramics, engineering plastics, or combinations thereof.

11. The probe head of claim 1, wherein a length of a side of the film is greater than 10 mm.

12. The probe head of claim 1, wherein the first probing zone and the second probing zone are substantially arranged along a direction, and each of the first probing zone and the second probing zone has a first length in the direction, and the non-probing zone has a second length in the direction, and the second length is greater than the first length.

13. The probe head of claim 1, wherein a stiffness of the supporting frame is greater than that of the film, and thus the film is supported by the supporting frame.

14. The probe head of claim 1, wherein a distance between the spacer and the first guiding board is greater than a thickness of the positioning assembly.

15. The probe head of claim 1, wherein the probes do not pass through or contact the rib portion.

16. The probe head of claim 1, wherein the first probing zone is corresponding to an area of a first device under test, and the non-probing zone is corresponding to an area of a second device under test and a scribing line.

7. A probe head, comprising:
a first guiding board;
a second guiding board stacked over the first guiding board, wherein an accommodating space is formed between the first guiding board and the second guiding board;
a spacer that is disposed on the second guiding board and is located in the accommodating space;
a positioning assembly that is disposed and supported on the second guiding board and is movably retained between the spacer and the first guiding board, the positioning assembly comprising:
a supporting frame comprising at least one rib portion; and
a film fixed to the supporting frame; and
a plurality of probes passing through the first guiding board, the second guiding board, and the film, wherein the probes at least form a first probing zone and a second probing zone, a non-probing zone is formed between the first probing zone and the second probing zone and are arranged along a direction from the first, probing zone to the second probing zone, and a length of the non-probing zone is greater than that of the first probing zone.

18. The probe head of claim 17, wherein the probes do not pass through or contact the rib portion.

19. The probe head of claim 17, wherein at least five rows and at least five columns of the probes pass through the first probing zone.

20. The probe head of claim 17, wherein the first probing zone is corresponding to an area of a first device under test, and an area of the non-probing zone is larger than or equal to an area of a second device under test and a scribing line.
